(19) United States
(12) Patent Application Publication
(10) Pub. No.: US 2025/0364360 A1
(43) Pub. Date: Nov. 27, 2025

(54) METHOD OF FORMING STACKED SEMICONDUCTOR DEVICES WITH CARBON NANOFIBER STRUCTURES AND ASSOCIATED SYSTEMS AND METHODS

(71) Applicant: Micron Technology, Inc., Boise, ID (US)

(72) Inventor: Wei Zhou, Boise, ID (US)

(21) Appl. No.: 19/213,855

(22) Filed: May 20, 2025

Related U.S. Application Data
(60) Provisional application No. 63/651,134, filed on May 23, 2024.

(51) Int. Cl. H01L 23/373; H01L 25/00; H01L 25/065; H01L 25/18; H10B 80/00

(52) U.S. Cl. CPC H01L 23/3733; H01L 25/0657; H01L 25/18; H01L 25/50; H10B 80/00; H01L 2225/06541; H01L 2225/06589

(57) ABSTRACT

Systems and methods for manufacturing stacked semiconductor devices, and the resulting stacked semiconductor devices, are disclosed herein. The method can begin by growing a carbon nanofiber layer on a first wafer that is independent from other components of the stacked semiconductor device (e.g., any of the dies in the stacked semiconductor component). The method can then include depositing a mold material over the carbon nanofiber layer, forming a plurality of cavities in the carbon nanofiber layer, and dispensing a polymer layer over the carbon nanofiber layer. The first wafer can then be aligned with a second wafer such that the cavities in the carbon nanofiber layer are each individually aligned with a die stack carried by the second wafer. Once aligned, the method can include attaching the carbon nanofiber layer to the second wafer via the polymer layer.

### CROSS-REFERENCE TO RELATED APPLICATION(S)

The present application claims priority to U.S. Provisional Patent Application No. 63/651,134, filed May 23, 2024, the disclosure of which is incorporated herein by reference in its entirety.

### TECHNICAL FIELD

The present technology is generally directed to methods of forming stacked semiconductor devices with thermal components and more specifically to systems and methods for forming tightly coupled memory devices with carbon nanofiber structures to transport heat.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet market demands, such as by reducing the overall device footprint, can often introduce challenges in other aspects, such as maintaining circuit robustness and/or failure detectability.

### BRIEF DESCRIPTION OF THE DRAWINGS

FIG. 1 is a partially schematic cross-sectional diagram of a tightly coupled memory device configured in accordance with some embodiments of the present technology.

FIG. 2 is a flow diagram of a process for manufacturing a stacked semiconductor device with a carbon nanofiber thermal component in accordance with some embodiments of the present technology.

FIGS. 3A-3G are partially schematic cross-sectional diagrams of semiconductor substrates at various stages of a process for manufacturing a tightly coupled memory device with a carbon nanofiber thermal component in accordance with some embodiments of the present technology.

FIG. 4 is a partially schematic cross-sectional diagram of a tightly coupled memory device configured in accordance with some embodiments of the present technology.

FIG. 5 is a flow diagram of a process for manufacturing a stacked semiconductor device with a carbon nanofiber thermal component in accordance with some embodiments of the present technology.

FIG. 6 is a schematic view of a system that includes a semiconductor die assembly configured in accordance with embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular embodiments described.

### DETAILED DESCRIPTION

### Overview

High data reliability, high speed of memory access, lower power consumption, and reduced chip and/or package size are features that are demanded from semiconductor memory. Stacked semiconductor devices and three-dimensional (3D) memory devices have been introduced to help meet these demands. These devices can be formed by stacking memory devices vertically and interconnecting the dies using through-silicon (or through-substrate) vias (TSVs). The benefits of these devices include shorter channel lengths and/or a large number of available connections which can both help increase bandwidth, reduce circuit delays, and/or reduce power consumption. Additionally, or alternatively, these devices can have a considerably smaller footprint than devices connected by another substrate (e.g., a package substrate).

In a specific, non-limiting example, one or more memory dies (e.g., DRAM dies, SRAM dies, and/or the like) can be stacked on top of a logic die (or other functional die) and interconnected with the logic die through TSVs to form a tightly coupled memory device. The TSVs can provide a relatively large bandwidth and/or relatively low latency as compared to memory devices that must be accessed through one or more route lines, input/output (IO) circuits external to the logic die, and/or cache memories. Further, the TSVs allow the logic die to directly access the memory dies in a deterministic manner (e.g., within a fixed time defined by the bandwidth of the TSVs and the response speed of the memory dies). Accordingly, the tightly coupled memory can allow the logic die to access the memory dies to execute various time-critical routines (e.g., various real-time processing tasks) and complete the routines in a relatively small, predictable amount of time.

The stacked memory dies, however, create separation between the logic die and one or more heat-dispersing components (e.g., thermal interface materials and/or the like) and/or airflow over the stacked semiconductor device. As a result, the heat generated by processing in the logic die tends to build up during operation of the tightly coupled memory device, eventually causing deleterious effects in the tightly coupled memory device. For example, the heat can require increased refresh rates in the memory dies, cause errors (e.g., memory misses) in the memory dies, disrupt electrical connections, and/or degrade circuits in the tightly coupled memory devices. Accordingly, many stacked semiconductor devices include one or more thermal structures positioned to carry heat away from the logic die.

Carbon nanofibers are more thermally conductive than copper, tin, and/or other materials typically included in the thermally conductive structure. Accordingly, it would be beneficial to incorporate carbon nanofibers into the thermal structure to increase the amount of heat that can be transported away from the logic die (and/or any memory dies the thermal structure is in contact with). However, current processes for growing carbon nanofibers require more heat than the stacked memory devices can withstand (e.g., before circuits and/or connections are damaged). Additionally, the resulting carbon nanofibers are susceptible to damage during later packaging processes that can undermine their ability to transport heat away from the logic die.

Processes for forming stacked semiconductor devices, resulting stacked semiconductor devices, and associated systems and methods, are disclosed herein to address the challenges discussed above. For example, as discussed in more detail below, the process can include growing a carbon nanofiber layer on a first wafer, separate from a second wafer containing one or more stacked semiconductor devices (e.g., tightly coupled memory devices). By growing the carbon nanofiber layer on a separate wafer, the process can avoid (or reduce) damage to the memory dies in the stacked device associated with growing the carbon nanofibers. However, the process must then attach the first wafer (and the carbon nanofiber layer) to the second wafer without damaging the carbon nanofiber layer. For example, the process can include depositing a mold material (e.g., an epoxy material) over and/or into the carbon nanofiber layer, forming a plurality of cavities in the carbon nanofiber layer, then depositing a polymer layer over the carbon nanofiber layer. The mold material can help provide mechanical strength to the carbon nanofiber layer, thereby protecting the carbon nanofibers during cavity formation and/or later steps in the process.

The cavities can each correspond to an individual die stack on the second wafer (e.g., one or more memory dies). Further, each of the die stacks can be a part of an individual stacked semiconductor device, with a logic die carried by and/or formed in a substrate of the second wafer. Once the cavities are formed, the process can align the second wafer with the first wafer such that each of the cavities formed in the first wafer is aligned with the corresponding die stack on the second wafer. The process can then include attaching the first wafer to the second wafer via the polymer layer, removing a base material of the first wafer, and singulating the individual stacked semiconductor devices from each other.

In another example, a stacked semiconductor device resulting from the processes disclosed herein can include a logic die, as well as a stack of one or more semiconductor dies (e.g., memory dies) and a thermal component each carried by an upper surface of the logic die. More specifically, the upper surface can include a die-attach region and a shelf region peripheral to at least a portion of the die-attach region. The stack of semiconductor dies can be carried by the die-attach region and the thermal component carried by the shelf region (e.g., peripheral to and/or circumferentially surrounding the stack of semiconductor dies). The thermal component (sometimes also referred to herein as a “carbon nanofiber component,” “CNF component,” “thermally conductive component,” and/or the like) can include a carbon nanofiber component and a polymer layer attaching the carbon nanofiber component to the shelf region of the upper surface. The carbon nanofiber component can include a plurality of carbon nanofibers and a mold material at least partially encasing the plurality of carbon nanofibers. The plurality of carbon nanofibers can be positioned and/or oriented in a vertical direction to transfer heat vertically away from the shelf region of the upper surface of the logic die.

Further, the thermal component can be attached (and thermally coupled) to the shelf region of the logic die by a polymer material. In some embodiments, the thermal component is also attached (and thermally coupled) to the stack of semiconductor dies by the polymer material. Attaching the thermal component to the stack of semiconductor dies can help improve a mechanical strength of the resulting stacked semiconductor device, reducing the chance that the stacked semiconductor device is damaged in later packaging processes. Additionally, or alternatively, attaching the thermal component to the stack of semiconductor dies can allow the thermal component to transport heat away from the dies therein.

For ease of reference, the stacked semiconductor devices, and components thereof, are sometimes described herein with reference to top and bottom, upper and lower, upwards and downwards, and/or horizontal plane, x-y plane, vertical, or z-direction relative to the spatial orientation of the embodiments shown in the figures. It is to be understood, however, that the stacked semiconductor devices, and components thereof, can be moved to, and used in, different spatial orientations without changing the structure and/or function of the disclosed embodiments of the present technology.

Further, although primarily discussed herein as in the context of manufacturing tightly coupled memory devices, one of skill in the art will understand that the scope of the invention is not so limited. For example, the systems and methods disclosed herein can also produce a variety of other stacked semiconductor devices and/or related components (e.g., high-bandwidth memory cubes, other stacked memory devices, and/or the like). Accordingly, the scope of the invention is not confined to any subset of embodiments, and is confined only by the limitations set out in the appended claims.

Specific details of several embodiments of semiconductor wafers, singulation thereof, and associated systems and methods are described below. The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

Further, unless the context indicates otherwise, structures disclosed herein can be formed using conventional semiconductor manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques. Some of the techniques may be combined with photolithography processes.

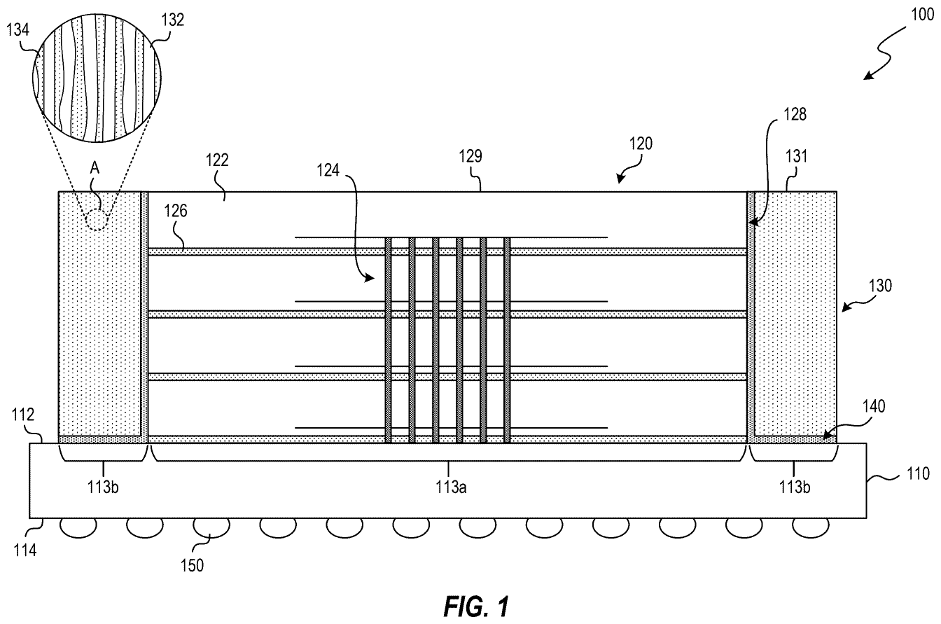

FIG. 1 is a partially schematic cross-sectional diagram of a tightly coupled memory device 100 configured in accordance with some embodiments of the present technology. In the illustrated embodiments, the tightly coupled memory device 100 (“memory device 100”) includes a base die 110 (e.g., a logic die, computational die, and/or the like) as well as a die stack 120 and a thermal component 130 each carried by an upper surface 112 of the base die 110. More specifically, the die stack 120 is integrated with (e.g., carried by and electrically coupled to) a die-attach region 113a of the upper surface 112 (sometimes also referred to herein as an “active surface” and/or the like) while the thermal component 130 is thermally coupled to a shelf region 113b of the upper surface 112. As illustrated in the cross-section of FIG. 1, the shelf region 113b (sometimes also referred to herein as a “peripheral portion,” a “thermal region,” and/or the like) can be peripheral to the die-attach region 113a (sometimes also referred to herein as a “central portion,” a “connection region,” and/or the like). In some embodiments, the shelf region 113b fully surrounds (e.g., circumferentially surrounds) the die-attach region 113a (e.g., fully tracing a perimeter of the upper surface 112). In some embodiments, the shelf region 113b partially surrounds the die-attach region 113a.

The die stack 120 includes a plurality of memory dies 122 (e.g., DRAM dies, SRAM dies, and/or the like) that are communicably coupled by a plurality of TSVs 124 extending through the die stack 120. In some embodiments, each of the memory dies 122 (and segments of the plurality of TSVs 124 therein) are integrated via interconnect structures (e.g., solder structures, copper posts, and/or other conductive structures) between each of the memory dies. In the illustrated embodiment, each of the memory dies 122 is integrated through hybrid bonds formed between the memory dies 122. The hybrid bonds can include metal-metal bonds formed between segments of the plurality of TSVs 124 (and/or any bond pads therein) in the memory dies as well as substrate-substrate bonds between the memory dies 122. In the illustrated embodiment, the die stack 120 includes a dielectric substrate 126 between each of the memory dies 122 resulting from a fusion of dielectric layers therebetween.

As further illustrated in FIG. 1, the plurality of TSVs 124 can be communicably coupled to the upper surface 112 of the base die 110 (e.g., through interconnect structures and/or metal-metal bonds to conductive structures in the upper surface 112), hereby communicably coupling each of the memory dies 122 is to the base die 110. Accordingly, the plurality of TSVs 124 allows the base die 110 to directly access each of the memory dies 122 during operation of the memory device 100. Further, the plurality of TSVs 124 can provide a relatively high-bandwidth communication channel with each of the memory dies 122 (e.g., as compared to memory dies accessed through one or more traces in a package substrate). As a result of the high bandwidth and the tight coupling between the base die 110 and the die stack 120, the base die 110 can access data in each of the memory dies 122 in a fast, predictable amount of time. In turn, the fast communication between the memory dies 122 and the base die 110 allows the memory device 100 to be suitable for various memory-intensive computer processes. Further, the predictability of the access time (e.g., as compared to a cache memory that may have a cache miss and need to retrieve data) allows the memory device 100 to be suitable for various time-sensitive processes, such as real-time processing applications and/or streaming processes.

These processes, however, can generate significant amounts of heat in the base die 110. The heat, if not addressed, can threaten deleterious effects in the die stack 120 and/or the base die 110 (e.g., requiring increased refresh rates, causing data losses, damaging circuits and/or communication lines, and/or the like). The thermal component 130 can help transport heat away from the base die 110 to reduce an overall temperature of the memory device 100 and/or to help prevent the heat from flowing through the die stack 120. To do so, as best illustrated in the blown-up view of region A of the thermal component 130, the thermal component 130 includes carbon nanofibers 132 that are at least partially surrounded by a mold material 134. While the carbon nanofibers 132 are more thermally conductive than copper and/or various other common thermal diffusion materials, the process of growing the carbon nanofibers 132 can be damaging to the base die 110 and/or the memory dies 122.

Accordingly, as discussed in more detail below, the thermal component 130 can be manufactured separately from the base die 110 and/or the die stack 120, then attached to the upper surface 112. While the separate manufacturing process can help protect circuits in the base die 110 and/or the die stack 120, the separate manufacturing process also creates challenges for the manufacturing process. For example, the carbon nanofibers 132 can be too fragile to undergo packaging processes related to attaching the thermal component 130 to the upper surface 112 of the base die 110. Accordingly, as further illustrated in the blown-up view of region A, the carbon nanofibers 132 can be surrounded by the mold material 134 (e.g., a cured epoxy and/or another suitable mold material). Said another way, the mold material 134 can fill gaps between the carbon nanofibers 132. As a result, the mold material 134 can provide mechanical strength to the thermal component 130 and/or otherwise reduce the chance that the carbon nanofibers 132 are damaged during various packaging (and other) processes. Additionally, the mold material 134 can help hold the carbon nanofibers 132 in a vertical direction (or generally vertical direction), thereby establishing vertical pathways for heat to flow away from the base die 110. Said another way, the vertical orientation of the carbon nanofibers 132 can help the carbon nanofibers quickly transport heat away from the base die 110 during operation of the memory device 100.

In another example, the thermal component 130 must be attached (and thermally coupled) to the other components of the memory device 100. Accordingly, as further illustrated in FIG. 1, the thermal component 130 can include a polymer layer 140 that attaches the thermal component 130 to the upper surface 112 of the base die 110. As a result, the polymer layer 140 places the thermal component 130 in contact with the upper surface 112, thereby allowing the carbon nanofibers 132 to transport heat away from the base die 110.

In the illustrated embodiment, the polymer layer 140 also attaches the thermal component 130 to sidewalls 128 of the die stack 120. As a result, the polymer layer 140 places the thermal component 130 in contact with the memory dies 122, thereby allowing the carbon nanofibers 132 to transport heat away from the memory dies 122. Additionally, or alternatively, the attachment between the thermal component 130 and the die stack 120 can help improve an overall mechanical strength of the memory device 100. As a result, the attachment between the thermal component 130 and the die stack 120 can help reduce the chance that various packaging processes and/or downstream impacts on the memory device 100 will cause damage to the memory device 100.

In some embodiments, however, the memory device 100 does not include the polymer layer 140 attaching the thermal component 130 to the sidewalls 128 of the die stack. In such embodiments, the thermal component 130 can be at least partially thermally isolated from the die stack 120, thereby creating a dedicated thermal pathway away from the base die 110. In some such embodiments, the memory device 100 can include an insulating material (e.g., a non-conductive mold material) in the space between the thermal component 130 and the die stack 120 to help supplement the overall mechanical strength of the memory device 100.

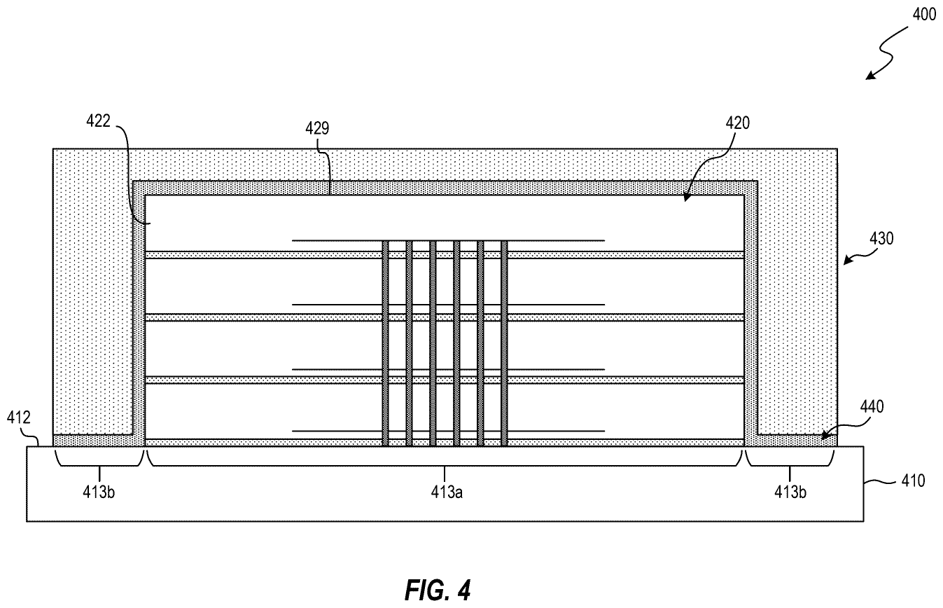

In the embodiments illustrated in FIG. 1, the thermal component 130 forms sidewalls for the memory device 100. As a result, an uppermost surface 129 of the die stack 120 is exposed. In some embodiments, the uppermost surface 129 is coplanar (or generally coplanar) with a top surface 131 (sometimes also referred to herein as an “outermost surface” and/or the like) of the thermal component 130. As a result, a thermal diffusion component (e.g., a thermal interface material) can be formed over and/or attached to the uppermost surface 129 and the top surface 131. In some embodiments (e.g., as discussed in more detail below with reference to FIG. 4), the thermal component 130 at least partially covers the uppermost surface, thereby forming a lid for the memory device 100.

FIG. 1 also illustrates additional details on the memory device 100 according to some embodiments of the present technology. For example, the base die 110 includes a lower surface 114 opposite the upper surface 112 and the memory device 100 can include one or more interconnect structures 150 coupled to the lower surface 114. In various embodiments, the interconnect structures 150 can include solder structures (e.g., solder balls), metallic pillars, conductive paste, and/or various other suitable conductive materials to electrically couple the base die 110 to an external component (e.g., a package substrate, a printed circuit board, an interposer substrate (e.g., a silicon interposer), and/or the like, not shown). However, it will be understood that, in some embodiments, the base die 110 can include bond pads (not shown) on the lower surface 114 that can be directly coupled (e.g., via metal-metal bonds) to conductive structures on the external component.

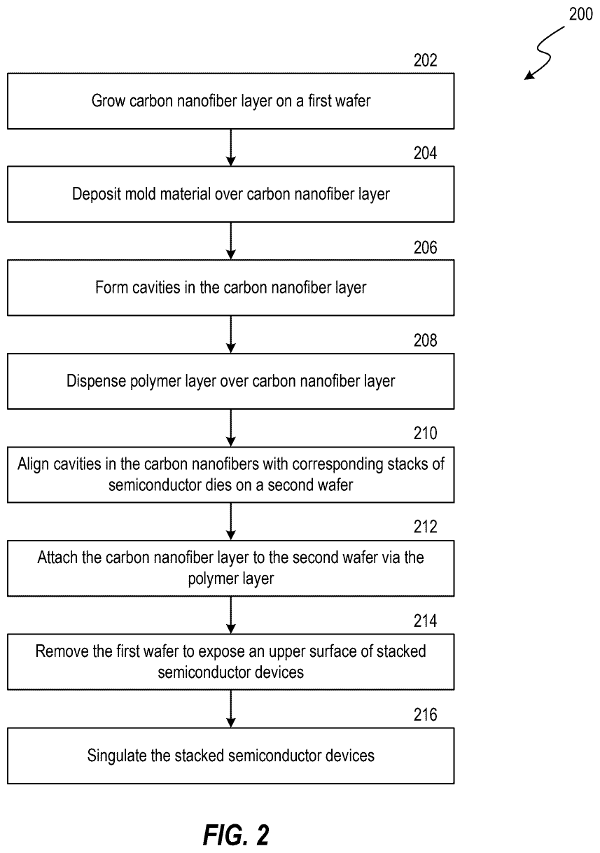

FIG. 2 is a flow diagram of a process 200 for manufacturing a stacked semiconductor device with a carbon nanofiber thermal component in accordance with some embodiments of the present technology. The process 200 can, for example, create a tightly coupled memory device 100 of the type discussed above with reference to FIG. 1. It will be understood, however, that the process 200 is not so limited, and may be used to create a variety of other stacked semiconductor devices with a carbon nanofiber thermal component.

The process 200 begins at block 202 by growing a carbon nanofiber layer on a first wafer. The first wafer can be independent of other components of the stacked semiconductor device. As a result, the growing process can be implemented at high temperatures (and/or with exposure to any suitable chemicals) without risking damage to any of the other components of the stacked semiconductor device. The growing process at block 202 can form the carbon nanofiber layer with each individual carbon nanofiber oriented in a generally vertical direction, thereby establishing a plurality of generally vertical pathways for heat through the carbon nanofiber layer.

At block 204, the process 200 includes depositing a mold material over the carbon nanofiber layer. The mold material can fill in gaps and/or spaces between the individual carbon nanofibers to help improve a rigidity and/or various other mechanical properties of the carbon nanofiber layer. As a result, the mold material can help improve handling properties of the carbon nanofiber layer, thereby allowing the carbon nanofiber layer to go through various other packaging processes without damaging (or with reduced damage to) the individual carbon nanofibers. Said another way, the mold material can help maintain the structure and/or orientation of the individual carbon nanofibers in the carbon nanofiber layer throughout the rest of the process 200 and/or further packing processes on the resulting stacked semiconductor device. In some embodiments, the mold material can be an epoxy resin that can be flowed over (and into) the carbon nanofiber layer, and then cured.

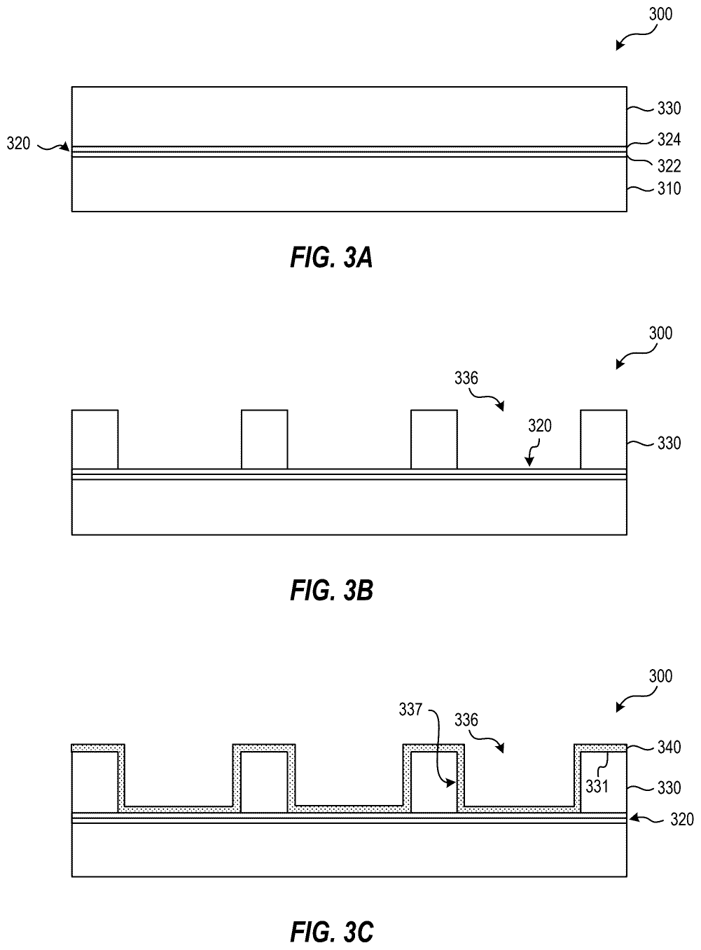

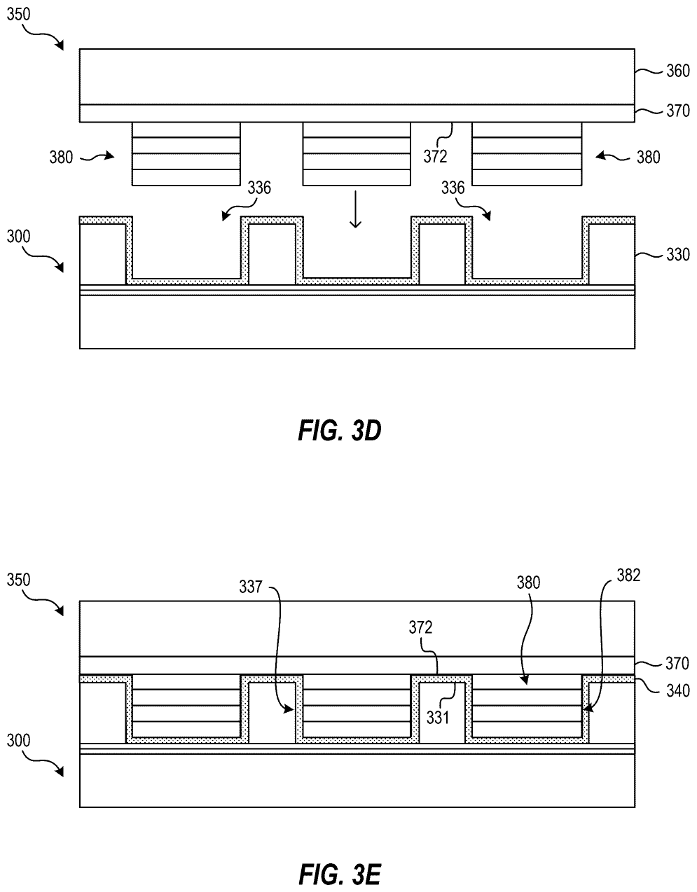

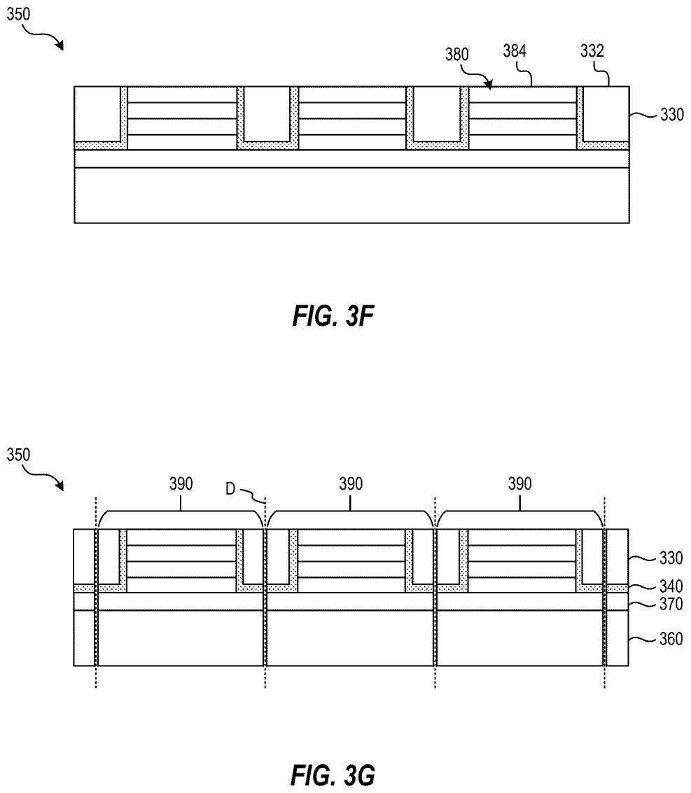

At block 206, the process 200 includes forming cavities in the carbon nanofiber layer. Forming the cavities at block 208 can include a laser etching process, a chemical etching process mechanical grinding processes, and/or any other suitable removal processes. Each of the cavities can generally correspond to a stack of semiconductor dies carried by a second wafer (discussed in more detail below). For example, each of the cavities can have a footprint sized to accommodate the die stack 120 discussed above with reference to FIG. 1. In some embodiments, the cavities extend fully through the carbon nanofiber layer, thereby forming openings exposing a surface of the first wafer. As a result, as discussed below with reference to FIGS. 3A-3G, the carbon nanofiber layer can form sidewalls around the stack of semiconductor dies while leaving an uppermost surface of the stack of semiconductor dies exposed. In some embodiments, the cavities extend to an intermediate depth in the carbon nanofiber layer. As a result, as discussed below with reference to FIG. 4, the carbon nanofiber layer can form a lid over the stack of semiconductor dies.

At block 208, the process 200 includes dispensing a polymer layer over the carbon nanofiber layer. The deposition can be accomplished via a spin coating process, spray coating process, a slot die coating process, and/or any other suitable process. In some embodiments, the dispensing process at block 208 is controlled to deposit the polymer layer in varying thicknesses over the carbon nanofiber layer. Purely by way of example, the resulting polymer layer can have a larger thickness on sidewalls of the cavities. As a result, the cavities can provide a larger clearance for the corresponding stack of semiconductor dies while ensuring that the carbon nanofiber layer will be attached to the corresponding stack of semiconductor dies (e.g., thereby provide greater tolerance for alignment). Additionally, or alternatively, the additional thickness of the polymer layer on the sidewalls of the cavities can provide additional polymer to be squeezed out of the cavities, thereby helping ensure that the carbon nanofiber layer is fully attached to the other components of the stacked semiconductor device. In some embodiments, the dispensing process at block 208 is controlled to prevent the polymer layer from coating the sidewalls of the cavities of the carbon nanofiber layer. In such embodiments, the carbon nanofiber layer can be thermally isolated from the corresponding stack of semiconductor dies (e.g., to create a dedicated thermal pathway away from base dies in the stacked semiconductor devices).

At block 210, the process 200 includes aligning the cavities in the carbon nanofiber layer with the corresponding stack of semiconductor dies on a second wafer. In some embodiments, the second wafer includes a base substrate having a plurality of base dies (e.g., logic dies, interface dies, processing dies, and/or the like) formed therein and a plurality of die stacks carried by the base substrate over a corresponding base die. Each pair of a base die and a die stack can form one of the corresponding stack of semiconductor dies that is aligned with one of the cavities at block 210.

At block 212, the process 200 includes attaching the carbon nanofiber layer to the second wafer via the polymer layer. Returning to the example above, the polymer layer can attach the carbon nanofiber layer to the base substrate and/or sidewalls of each of the corresponding die stacks. The attachment forms a mechanical and thermal connection between the carbon nanofiber layer and the other components of the stacked semiconductor device (e.g., between the carbon nanofiber layer and the base die formed in the base substrate and/or between the carbon nanofiber layer and sidewalls of the die stack).

At block 214, the process 200 includes removing the first wafer substrate to expose an upper surface of the stacked semiconductor device. The removal process at block 214 can include a back grinding process, a laser etching process, a chemical etching process, and/or any other suitable process. In some embodiments, the process 200 at block 214 exposes a top surface of the carbon nanofiber layer as well as an uppermost surface of the die stack. In some such embodiments, the top surface of the carbon nanofiber layer and the uppermost surface of the die stack are coplanar (or generally coplanar) after the removal process at block 214. In some embodiments, the process 200 at block 214 exposes only a top surface of the carbon nanofiber layer (e.g., when the carbon nanofiber layer forms a complete lid of the stack of semiconductor dies.

At block 216, the process 200 includes singulating the stacked semiconductor devices from each other. The singulation process can include a mechanical dicing process (e.g., a blade dicing process), a laser dicing process, a stealth dicing process, and/or any other suitable singulation process. Once singulated, the stacked semiconductor devices can be implemented into various other packaging processes (e.g., integrated with a package substrate, an interposer substrate, a printed circuit board, and/or the like).

FIGS. 3A-3G are partially schematic cross-sectional diagrams of semiconductor substrates at various stages of a process for manufacturing a stacked semiconductor device with a carbon nanofiber thermal component in accordance with some embodiments of the present technology. The process illustrated in FIGS. 3A-3G is generally similar to the process 200 discussed above with reference to FIG. 2. Accordingly, a process of the type illustrated in FIGS. 3A-3G can be executed to manufacture tightly coupled memory devices with a carbon nanofiber thermal component. However, it will be understood that a process of the type illustrated in FIGS. 3A-3G can be executed to manufacture a variety of other stacked semiconductor devices and/or similar components.

FIG. 3A illustrates a first wafer 300 after growing a carbon nanofiber layer 330 on a first wafer substrate 310. As illustrated in FIG. 3A, growing the carbon nanofiber layer 330 on the first wafer substrate 310 can be predicated by depositing a base layer 320 over the first wafer substrate 310. The base layer 320 can help grow the carbon nanofiber layer 330 and/or help remove the first wafer substrate 310 from the carbon nanofiber layer 330 in later processes. For example, as illustrated in FIG. 3A, the base layer 320 includes a dielectric layer 322 (e.g., a silicon oxide layer) that insulates the first wafer substrate 310 from the carbon nanofiber layer 330 and a seed layer 324 (e.g., a tin and/or copper seeding layer) deposited over the dielectric layer 322. The first wafer 300 can then be subjected to various heat and chemical conditions that cause individual carbon nanofibers to grow on the seed layer 324. The carbon nanofibers can then be surrounded by a mold material to mechanically support the carbon nanofibers, thereby completing the carbon nanofiber layer 330.

FIG. 3B illustrates the first wafer 300 after forming a plurality of cavities 336 (three illustrated, one labeled in FIG. 3B) in the carbon nanofiber layer 330. As discussed above, the cavities 336 can be formed by a laser etching process, a chemical etching process, a mechanical etching process, and/or any other suitable process to remove the mold material and the carbon nanofibers from the carbon nanofiber layer 330. In the illustrated embodiment, the cavities 336 extend fully through the carbon nanofiber layer 330 to expose the base layer 320. It will be understood, however, that the cavities 336 can be formed to an intermediate depth in the carbon nanofiber layer 330.

FIG. 3C illustrates the first wafer 300 after dispensing a polymer layer 340 over the carbon nanofiber layer 330. As illustrated in FIG. 3C, the polymer layer 340 can coat an interface surface 331 of the carbon nanofiber layer 330 as well as sidewalls 337 of the cavities 336. As a result, as discussed above, the polymer layer 340 can help attach the carbon nanofiber layer to both a base die (e.g., the base die 110 of FIG. 1) and a die stack (e.g., the die stack 120 of FIG. 1) carried thereon. In some embodiments, the polymer layer 340 is dispensed with a uniform (or generally uniform) thickness. In some embodiments, the polymer layer 340 is dispensed with a varying thickness. Purely by way of example, portions of the polymer layer 340 dispensed on the sidewalls 337 of the cavities 336 can be thicker than portions of the polymer layer 340 dispensed over the interface surface 331 of the carbon nanofiber layer 330.

FIG. 3D illustrates the first wafer 300 being aligned with various structures on a second wafer 350. In the illustrated embodiment, the second wafer 350 includes a second wafer substrate 360, a base die layer 370 formed on the second wafer substrate 360, and a plurality of die stacks 380 (three illustrated in FIG. 3D) carried by an active surface 372 of the base die layer 370. The base die layer 370 can include a base die (e.g., a logic die, interface die, processing die, and/or the like) for each of the die stacks 380. Further, the die stacks 380 can include one or more semiconductor dies (e.g., memory dies, such as DRAM dies, SRAM dies, and/or the like; logic dies; and/or any other suitable dies) integrated with the corresponding base die (e.g., communicably coupled via TSVs, such as the plurality of TSVs 124 of FIG. 1). Aligning the first wafer 300 with the second wafer 350 can include aligning the cavities 336 in the carbon nanofiber layer with the die stacks 380 on the second wafer 350.

Once aligned, the first wafer 300 can be attached to the second wafer 350. More specifically, as illustrated in FIG. 3E, the polymer layer 340 can attach the carbon nanofiber layer 330 to various components of the second wafer 350. For example, the polymer layer 340 can attach the interface surface 331 of the carbon nanofiber layer 330 to an active surface 372 of the base die layer 370. As a result, the polymer layer 340 can physically and thermally couple the carbon nanofiber layer 330 to the base die layer 370. In another example, the polymer layer 340 can attach the sidewalls 337 of the cavities 336 in the carbon nanofiber layer 330 to sidewalls 382 of the die stacks 380. As a result, the polymer layer 340 can physically and thermally couple the carbon nanofiber layer 330 to the die stacks 380.

FIG. 3F illustrates the second wafer 350 after the first wafer 300 (FIG. 3E) has been removed from the system. The removal process can use various mechanical grinding processes (e.g., a back grinding process), chemical removal processes, laser removal processes, and/or the like to remove the first wafer substrate 310 and the base layer 320 (FIG. 3A). As illustrated in FIG. 3F, the removal process can expose a top surface 332 of the carbon nanofiber layer 330, as well as an uppermost surface 384 of the die stacks 380. In some embodiments, the removal process only exposes the top surface 332 of the carbon nanofiber layer 330 (e.g., when the carbon nanofiber layer 330 forms a full lid over the stacked semiconductor devices). In some embodiments, the process can then deposit and/or attach another component (e.g., a thermal interface material) to the top surface 332 of the carbon nanofiber layer 330 and/or the uppermost surface 384 of the die stacks 380.

FIG. 3G illustrates the second wafer 350 after each of the stacked semiconductor devices 390 thereon has been singulated. The singulation process can be completed by a blade dicing process, a laser dicing process, a stealth dicing process, and/or any other suitable process to singulate the stacked semiconductor devices 390 along dicing lines D. Purely by way of example, in a blade dicing process the blade can cut through the carbon nanofiber layer 330, the polymer layer 340, the base die layer 370, and the second wafer substrate 360 along the dicing lines D, thereby isolating each of the stacked semiconductor devices 390 from each other. In some embodiments, the second wafer substrate 360 is back-grinded before (or after) the singulation process to reduce an overall height of the stacked semiconductor devices 390. In some embodiments, the second wafer substrate 360 is fully removed before (or after) the singulation process.

FIG. 4 is a partially schematic cross-sectional diagram of a tightly coupled memory device 400 configured in accordance with some embodiments of the present technology. As illustrated in FIG. 4, the tightly coupled memory device 400 (“memory device 400”) is generally similar to the memory device 100 discussed above with reference to FIG. 1. For example, the memory device 400 includes a base die 410, a die stack 420 integrated with a die-attach region 413a of an upper surface of the base die 410, and a thermal component 430 carried by a shelf region 413b of the upper surface 412. The die stack 420 includes a plurality of memory dies 422 (e.g., DRAM dies, SRAM dies, and/or the like. Similar to the thermal component 130 discussed above with reference to FIG. 1, the thermal component 430 can include a plurality of carbon nanofibers encased in a mold material. The carbon nanofibers can be oriented in a vertical direction to transport heat away from the upper surface 412 of the base die 410. Further, the thermal component 430 includes a polymer layer 440 that attaches and thermally couples the thermal component 430 to the base die 410 and the die stack 420.

In the illustrated embodiment, however, the thermal component 430 fully encases the die stack 420 to form a lid for the memory device 400. Said another way, the thermal component 430 is positioned to transport heat vertically away from both the upper surface 412 of the base die and an uppermost surface 429 of the die stack 420. The thermal component 430 can result from, for example, a process of the type discussed above with reference to FIGS. 2 and 3A-3G where the cavities in the carbon nanofiber layer are formed to an intermediate depth of the carbon nanofiber layer.

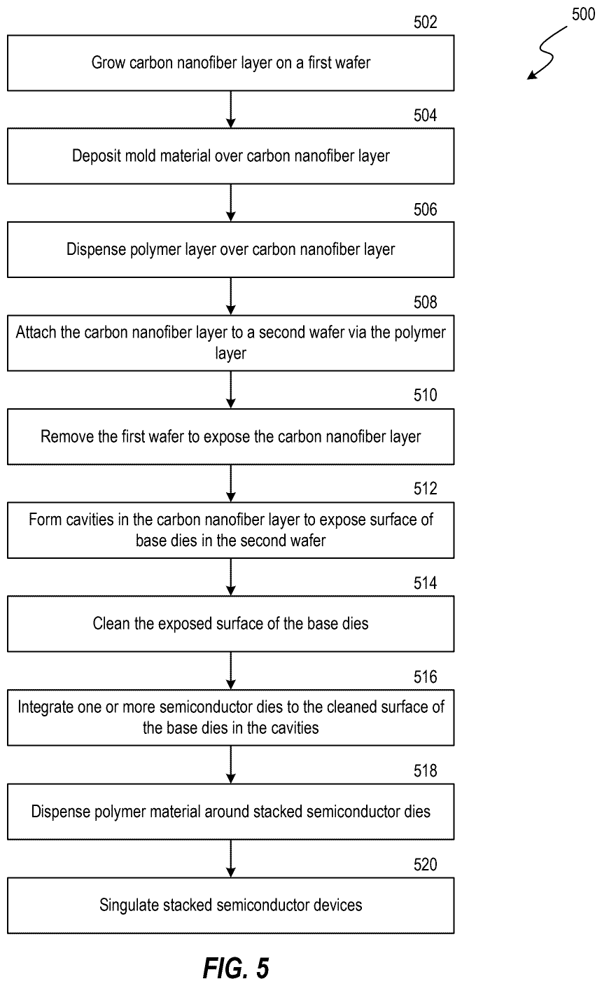

FIG. 5 is a flow diagram of a process 500 for manufacturing a stacked semiconductor device with a carbon nanofiber thermal component in accordance with some embodiments of the present technology. As illustrated, the process 500 is generally similar to the process discussed above with reference to FIG. 2. As a result, for example, the process 500 can create a tightly coupled memory device 100 of the type discussed above with reference to FIG. 1. In the illustrated embodiment, however, the process 500 is adapted to integrate die stacks (e.g., stacks of memory dies) with base dies of the stacked semiconductor substrates after attaching the thermal layer to the base die layer. The alternative order can help reduce a chance that the die stack is damaged while attaching the carbon nanofiber layer to the base die layer and/or help simplify aligning a carbon nanofiber wafer with a base die wafer.

The process 500 begins at block 502 with growing a carbon nanofiber layer on a first wafer. As discussed above, the first wafer can be independent of other components of the stacked semiconductor device. As a result, the growing process can implemented at high temperatures (and/or with exposure to any suitable chemicals) without risking damage to any of the other components of the stacked semiconductor device.

At block 504, the process 500 includes depositing a mold material over the carbon nanofiber layer. As discussed above, the mold material can fill in spaces between the individual carbon nanofibers to help improve a rigidity and/or various other mechanical properties of the carbon nanofiber layer. As a result, the mold material can help improve handling properties of the carbon nanofiber layer, thereby allowing the carbon nanofiber layer to go through various other packaging processes without damaging (or with reduced damage to) the individual carbon nanofibers.

At block 506, the process 500 includes dispensing a polymer layer over the carbon nanofiber layer. The deposition can be accomplished via a spin coating process, spray coating process, a slot die coating process, and/or any other suitable process.

Once the polymer layer is dispensed, at block 508, the process 500 includes attaching the carbon nanofiber layer to a second wafer via the polymer layer. The second wafer can include a base die layer formed thereon, but does not include any die stacks carried by the base die layer. As a result, the process 500 does not need to carefully align the first wafer with the second wafer before attaching the carbon nanofiber layer to the base die layer.

At block 510, the process 500 includes removing the first wafer substrate to expose a top surface carbon nanofiber layer. Similar to the discussion above, the removal process at block 510 can include a back grinding process, a laser etching process, a chemical etching process, and/or any other suitable process.

At block 512, the process 500 includes forming cavities in the carbon nanofiber layer. Forming the cavities at block 208 can include a laser etching process, a chemical etching process mechanical grinding processes, and/or any other suitable removal processes. Each of the cavities can generally expose an upper surface of a corresponding base die (e.g., a logic die, interface die, processing die, and/or the like) in the base die layer. At optional block 514, the process 500 can include cleaning the upper surface of each of the exposed base dies, for example to prepare the upper surface for a hybrid bonding process with the die stack.

At block 516, the process 500 includes integrating (e.g., stacking and electrically coupling) one or more semiconductor dies (e.g., memory dies, logic dies, and/or the like) with the upper surface of each of the exposed base dies in each of the cavities. In various embodiments, the integration process can include solder reflowing processes, metal-metal bonding processes, substrate-substrate bonding processes, and/or various other suitable processes to attach and electrically couple the semiconductor dies to the base dies. In some embodiments, the one or more semiconductor dies are stacked to the same height (or generally the same height) as the top surface of the carbon nanofiber layer. As a result, the top surface and an uppermost surface of the stacked semiconductor dies are coplanar (or generally coplanar) after the integration process at block 516.

At optional block 518, the process 500 includes dispensing a polymer material between the semiconductor dies stacked at block 516 and sidewalls of the cavities in the carbon nanofiber layer. The polymer material (and/or another suitable material, such as an epoxy mold) can help increase a mechanical strength of resulting stacked semiconductor devices by bracing the carbon nanofiber layer and the die stacks together. Additionally, or alternatively, the polymer layer can thermally couple the carbon nanofiber layer to the die stack to allow the carbon nanofiber layer to transport heat away from the die stack. In some embodiments, however, optional block 518 is omitted to thermally isolate the carbon nanofiber layer from the die stacks to create a dedicated thermal pathway away from the base dies.

At block 520, the process 500 includes singulating the stacked semiconductor devices from each other. Similar to the discussion above, the singulation process can include a mechanical dicing process (e.g., a blade dicing process), a laser dicing process, a stealth dicing process, and/or any other suitable singulation process. Once singulated, the stacked semiconductor devices can be implemented into various other packaging processes (e.g., integrated with a package substrate, an interposer substrate, a printed circuit board, and/or the like).

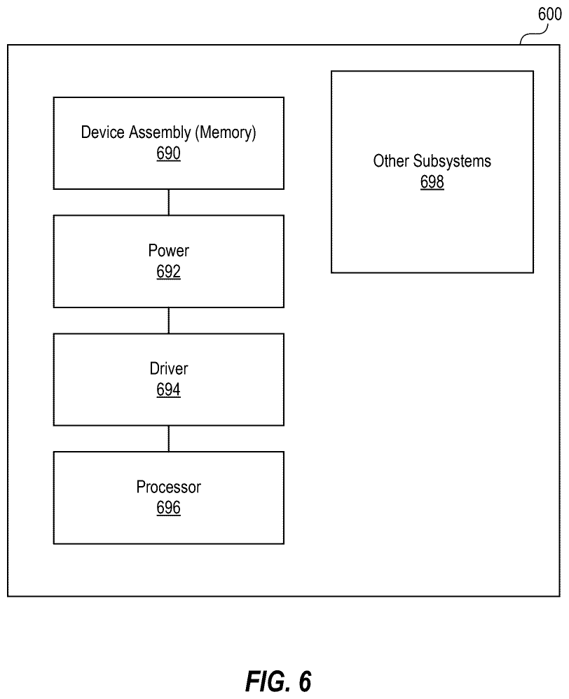

FIG. 6 is a schematic view of a system that includes a semiconductor die assembly configured in accordance with embodiments of the present technology. That is, the semiconductor device assemblies discussed above can be incorporated into any of a myriad of larger and/or more complex systems, a representative example of which is system 600 shown schematically in FIG. 6. The system 600 can include a memory 690 (e.g., SRAM, DRAM, flash, and/or other memory devices), a power supply 692, a drive 694, a processor 696, and/or other subsystems or components 698. Stacked semiconductor devices the manufactured using processes of the type discussed above with reference to FIGS. 2-3G, and 4 can be included in any of the elements shown in FIG. 6. Purely by way of example, the tightly coupled memory device discussed above with reference to FIG. 1 can be deployed in the memory 690 (e.g., in a managed NAND for us in various consumer electronics, automotive electronics, and the like; an SSD package; and/or any other suitable memory device).

The resulting system 600 can be configured to perform any of a wide variety of suitable computing, processing, storage, sensing, imaging, and/or other functions. Accordingly, representative examples of the system 600 include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of the system 600 include lights, cameras, vehicles, etc. With regard to these and other examples, the system 600 can be housed in a single unit or distributed over multiple interconnected units, e.g., through a communication network. The components of the system 600 can accordingly include local and/or remote memory storage devices and any of a wide variety of suitable computer-readable media.

### EXAMPLES

The present technology is illustrated, for example, according to various aspects described below. Various examples of aspects of the present technology are described as numbered examples (1, 2, 3, etc.) for convenience. These are provided as examples and do not limit the present technology. It is noted that any of the dependent examples can be combined in any suitable manner, and placed into a respective independent example. The other examples can be presented in a similar manner.

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately,” “generally,” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A stacked semiconductor device, comprising:
a logic die having an upper surface and a lower surface opposite the lower surface, wherein the upper surface includes a die-attach region and a shelf region peripheral to at least a portion of the die-attach region;
a stack of memory dies carried by the die-attach region of the upper surface;
a thermal component carried by the shelf region of the upper surface, wherein the thermal component includes a plurality of carbon nanofibers oriented in a vertical direction; and
a polymer layer attaching the thermal component to the shelf region of the upper surface to transfer heat vertically away from the shelf region of the upper surface through the plurality of carbon nanofibers.

2. The stacked semiconductor device of claim 1 wherein the thermal component further comprises a mold material surrounding the plurality of carbon nanofibers.

3. The stacked semiconductor device of claim 1 wherein the polymer layer further attaches the thermal component to sidewalls of each die in the stack of memory dies.

4. The stacked semiconductor device of claim 1 wherein the stack of memory dies includes a plurality of through substrate vias communicably coupling each die in the stack of memory dies to the upper surface of the logic die.

5. The stacked semiconductor device of claim 1 wherein the thermal component circumferentially surrounds the stack of memory dies.

6. The stacked semiconductor device of claim 1 wherein a top surface of the thermal component is coplanar with an uppermost surface of the stack of memory dies.

7. The stacked semiconductor device of claim 1 wherein the thermal component at least partially covers an uppermost surface of the stack of memory dies.

8. A method for manufacturing stacked semiconductor devices, the method comprising:
growing a carbon nanofiber layer on a first wafer;
forming a plurality of cavities in the carbon nanofiber layer;
dispensing a polymer layer over the carbon nanofiber layer;
aligning a second wafer with the first wafer, wherein the second wafer includes a plurality of stacked semiconductor devices formed thereon, wherein each of the plurality of stacked semiconductor devices includes a logic die and a die stack carried by the logic die, and wherein aligning the second wafer with the first wafer comprises aligning each of the plurality of cavities in the carbon nanofiber layer with a corresponding die stack from the plurality of stacked semiconductor devices; and
attaching the carbon nanofiber layer to the second wafer via the polymer layer.

9. The method of claim 8, further comprising depositing a mold material over the carbon nanofiber layer to fill gaps between individual carbon nanofibers in the carbon nanofiber layer.

10. The method of claim 8, further comprising singulating each of the plurality of stacked semiconductor devices.

11. The method of claim 8 wherein each logic die in the plurality of stacked semiconductor devices is formed in a base substrate on the second wafer, and wherein attaching the carbon nanofiber layer to the second wafer includes forming a bond between the polymer layer and the base substrate.

12. The method of claim 8 wherein attaching the carbon nanofiber layer to the second wafer includes forming a bond between the polymer layer and sidewalls of the die stack.

13. The method of claim 8 wherein each cavity in the plurality of cavities extends from an upper surface of the carbon nanofiber layer to a lower surface of the carbon nanofiber layer to expose at least a portion of the first wafer.

14. The method of claim 8 wherein each cavity in the plurality of cavities extends from an upper surface of the carbon nanofiber layer to an intermediate depth within the carbon nanofiber layer.

15. The method of claim 8 wherein growing the carbon nanofiber layer includes depositing a base layer over a wafer substrate of the first wafer, wherein the base layer includes a dielectric layer and a seed layer for the carbon nanofiber layer.

16. The method of claim 8 wherein the first wafer includes a wafer substrate, and wherein the method further comprises removing the wafer substrate to expose a top surface of the carbon nanofiber layer.

17. A method for manufacturing stacked semiconductor devices, the method comprising:
growing a carbon nanofiber layer on a wafer substrate of a first wafer;
dispensing a polymer layer over the carbon nanofiber layer;
attaching the carbon nanofiber layer to an upper surface of a base die layer on a second wafer via the polymer layer, wherein the base die layer includes a plurality of base dies for the stacked semiconductor devices formed therein;
removing the wafer substrate of the first wafer to expose a top surface of the carbon nanofiber layer;
forming cavities in the carbon nanofiber layer to expose the upper surface of the base die layer through the carbon nanofiber layer, wherein the cavities are formed over individual base dies from the plurality of base dies in the base die layer; and
integrating one or more semiconductor dies with the upper surface of the base die layer exposed by each of the cavities.

18. The method of claim 17, further comprising cleaning the upper surface of the base die layer exposed by each of the cavities.

19. The method of claim 17, further comprising depositing a mold material over the carbon nanofiber layer to fill gaps between individual carbon nanofibers in the carbon nanofiber layer.

20. The method of claim 17, further comprising dispensing a polymer material around the one or more semiconductor dies integrated with the upper surface of the base die layer in each of the cavities to attach the one or more semiconductor dies to the carbon nanofiber layer.
